(19) United States
(12) Patent Application Publication
(10) Pub. No.: US 2007/0194312 A1
(43) Pub. Date: Aug. 23, 2007

(54) Subpixel

(76) Inventors: Takashi Chuman, Saitama (JP); Satoru Ohta, Saitama (JP); Takahisa Tanabe, Saitama (JP)

Correspondence Address: SUGHRUE MION, PLLC, 2100 PENNSYLVANIA AVENUE, N.W., SUITE 800, WASHINGTON, DC, 20037, US

(21) Appl. No.: 10/594,039

(22) PCT Filed: Mar. 14, 2005
(86) PCT No.: PCT/JP05/04424

§ 371 Date: Sep. 25, 2006

(30) Foreign Application Priority Data
Mar. 26, 2004 (JP) P2004-091257

(51) Int. Cl. H01L 29/04

(52) U.S. Cl. 257/59

(57) ABSTRACT

There is provided a subpixel that is free from an increase in its overall size and can ensure a large size of its display portion, even when easily producible and inexpensive organic or amorphous Si thin film transistors are used. The subpixel includes one display portion and a plurality of thin film transistors for driving the display portion, wherein the plurality of thin film transistors are arranged such that their channels are in parallel to each another.

### TECHNICAL FIELD

The invention relates to a subpixel forming a pixel of a color display.

### BACKGROUND ART

Among active drive displays, a color display such as a liquid crystal display and an organic electroluminescence display includes a plurality of pixels capable of displaying different colors and thus can be changed to any voluntary color. For example, such a pixel is made up of a plurality of subpixels capable of displaying R (red), G (green) and B (blue) colors, respectively.

Such a subpixel includes one display portion such as an R (red)-display portion mentioned above and a plurality of thin film transistors (TFTs) for actively driving the display portion.

In association with a demand on high definition color displays, the size of such a subpixel is desired to be as small as possible, while there is another demand that a large size of a display portion forming such a subpixel be ensured.

Further, in thin film transistors for forming subpixels, there has been explored to use organic thin film transistors that need no high-temperature treatment for their production and thus can be produced at low cost or amorphous Si thin film transistors that can be relatively easily produced.

### DISCLOSURE OF THE INVENTION

### Problems to be Solved by the Invention

However, the charge mobility in the channel between source and drain is lower in organic thin film transistors or amorphous Si thin film transistors than in conventional polycrystalline Si thin film transistors, and therefore if such organic thin film transistors or the like are used, it is necessary to enlarge its channel portion. Accordingly, the thin film transistors resultantly become larger than the conventional polycrystalline Si thin film transistors.

However, the increase in the size of organic thin film transistors and as much increase in the overall size of a subpixel conflict with the demand that the overall size of a subpixel be reduced. An increase in the size of organic thin film transistors without a change in the overall size of subpixel leads to a reduction in the size of display portion, so that the demand that a large size of a display portion be ensured cannot be satisfied.

The present invention is provided in light of these problems, and it is an object of the invention to provide a subpixel that does not need an increase in its overall size and can ensure a large size of display portion, even when, for example, easily producible and inexpensive organic or amorphous Si thin film transistors are used.

### Means for Solving the Problems

The present invention recited in claim 1 for solving the problems is directed to a subpixel forming a pixel of a color display screen, including one display portion and a plurality of thin film transistors for driving the display portion, wherein the plurality of thin film transistors are arranged so that their channels are parallel to one another.

### BRIEF DESCRIPTION OF DRAWINGS

FIG. 1 is a front view of the subpixel of the present invention;

FIG. 2 is a schematic cross-sectional view along a line A-A in FIG. 1, showing the structure of an organic electroluminescence display device that forms a display portion 11 of the subpixel 10 of the present invention;

FIG. 3 is a schematic cross-sectional view along a line B-B in FIG. 1, showing a structure of an organic thin film transistor employed as a thin film transistor 13 of the subpixel 10 of the invention; and

FIG. 4 is a front view of a subpixel according to Comparative Example 1 .

### DESCRIPTION OF REFERENCE NUMERALS

10, 40 subpixel

11, 41 display portion

12, 42 thin film transistor (a switching thin film transistor)

13, 43 thin film transistor (a driving thin film transistor)

14, 44 storage capacitance

15, 45 glass substrate

20 anode

21 hole injection layer

22 hole transport layer

23 organic light-emitting layer

24 hole blocking layer

25 electron transport layer

26 electron injection layer

27 cathode

30 gate electrode

31 gate insulating film

32 source electrode

33 drain electrode

34 hexamethyldisilazane film

35 organic semiconductor layer

C channel

### Best Mode for Carrying Out the Invention

Hereinafter, the subpixel of the invention is more specifically described with reference to the drawings.

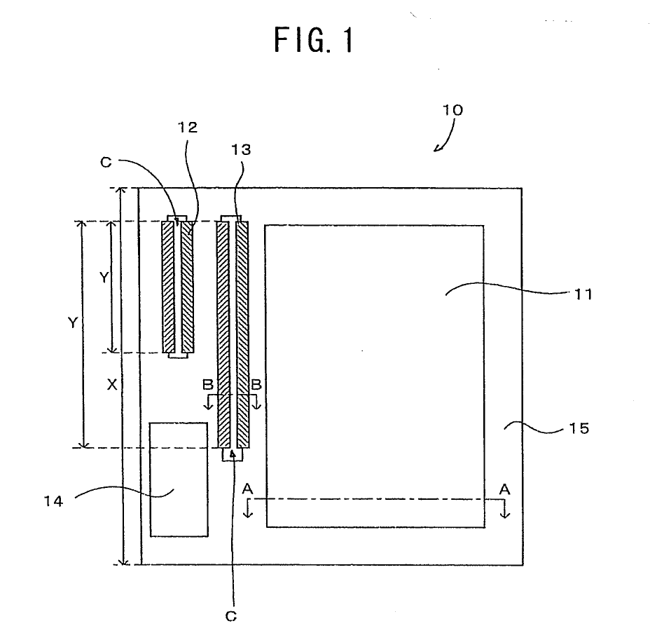

FIG. 1 is a front view of the subpixel of the invention.

As shown in FIG. 1, the subpixel of the invention 10 includes one display portion 11 and two thin film transistors 12 and 13 for driving the display portion 11 on a glass substrate 15. The two thin film transistors are a switching thin film transistor 12 and a driving thin film transistor 13. As shown in the drawing, a storage capacitance 14 and the like may be provided in addition to the display portion 11 and the thin film transistors 12 and 13. The subpixel 10 of the present invention is characterized in that the plurality of transistors (the switching thin film transistor 12 and the driving thin film transistor 13 in FIG. 1) are arranged such that their channels C and C are in parallel each other.

Arranging the plurality of thin film transistors with their channels placed in parallel each other allows an orderly arrangement of the display portion 11 and the thin film transistors 12 and 13 that form a subpixel, fineness of the subpixel being further in progress recent years. As a result, a size of the display portion 11 can be ensured to be large even when organic thin film transistors or amorphous Si thin film transistors are used as the thin film transistors. Namely, the size of the display portion 11 can be maintained large even when the organic thin film transistors or the like are made larger than conventional polycrystalline Si thin film transistors.

Furthermore, by arranging a plurality of thin film transistors with their channels placed in parallel each other, the plurality of thin film transistors can be uniformly rubbed in a rubbing process with respect to channel surfaces of thin film transistor, described later.

In the subpixel 10 of the present invention as described above, an overall size of subpixel and a size of thin film transistor, i.e. a width of channel, are not specifically limited. However, as shown in FIG. 1, when a length X of one side of the subpixel 10 is defined to be 1, a channel width Y of the thin film transistor 12 or 13, especially that of the driving thin film transistor 13, is preferably 0.4 or more, more preferably 0.5 or more.

For example, the display portion 11 forming the subpixel 10 of the present invention is not specifically limited to. For example, it maybe a liquid crystal display element or an organic electroluminescence display element.

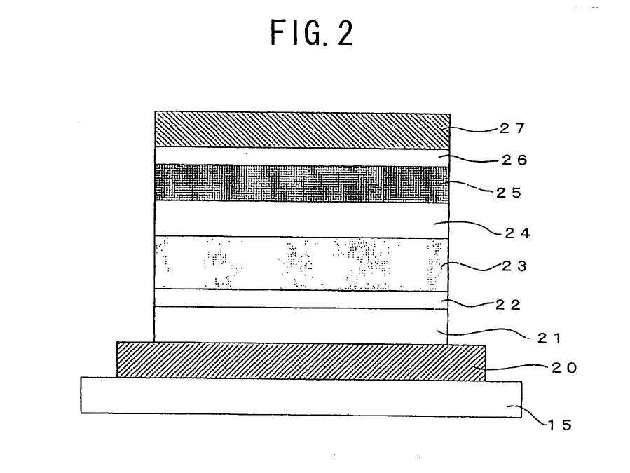

FIG. 2 is a schematic cross-sectional view along a line A-A in FIG. 1, showing a structure of organic electroluminescence (EL) display element that forms the display portion 11 of the subpixel 10 in the present invention.

As shown in FIG. 2, the organic electroluminescence display element as the display portion 11 is formed by sequentially laminating an anode 20, a hole injection layer 21, a hole transport layer 22, an organic light-emitting layer 23, a hole blocking layer 24, an electron transport layer 25, an electron injection layer 26, and a cathode 27 on a glass substrate 15. In this, various materials of from the anode 20 to the cathode 27 forming the organic electroluminescence (EL) display element is not specifically limited in the present invention. Any known conventional materials may be arbitrarily used for the components.

In the present invention, the method for manufacturing such an organic electroluminescence (EL) display element is also not specifically limited. For example, each of the layers may be sequentially laminated using a vacuum deposition equipment or the like.

The thin film transistors 12 and 13 forming the subpixel 10 of the present invention are not specifically limited. It maybe any type of thin film transistors (a so-called TFT). However, in order to maximize features and effects of the subpixel of the present invention, it is preferable to use organic thin film transistors or amorphous Si thin film. These thin film transistors are easily produced and available at a relatively low cost. In a case where an organic thin film transistor or an amorphous Si thin film transistor is used, there is a problem that their charge mobility is lower than that of conventional polycrystalline Si transistor. However, according to the subpixel of the present invention, since the width of channel can be increased as much, it is equivalent to enhancement of the charge mobility. Further, according to the subpixel of the invention, it becomes possible to sufficiently maintain the size of display portion because the channels are arranged in parallel even though the width of channel is increased.

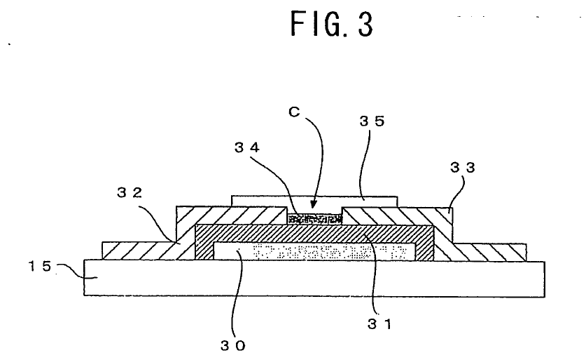

FIG. 3 is a schematic cross-sectional view along a line B-B in FIG. 1, showing the structure of an organic thin film transistor employed as the thin film transistor 13 of the subpixel 10 of the present invention. In its explanation, although the driving thin film transistor 13 is exemplified, an organic thin film transistor may be used as the switching thin film transistor 12 in a similar manner thereto.

The organic thin film transistor as the driving thin film transistor 13 is formed by sequentially laminating a gate electrode 30, a gate insulating film 31, a source electrode 32, a drain electrode 33, a hexamethyldisilazane film 34, and an organic semiconductor layer 35 on a glass substrate 15 as shown in the drawing. In the invention, the channel C of the thin film transistor corresponds to a part positioned between the source electrode 32 and the drain electrode 33.

The organic semiconductor layer 35 of such the organic thin film transistor may be made from any organic material that exhibits semiconducting properties. Examples of such the organic material are, in low molecular weight materials, phthalocyanine derivatives, naphthalocyanine derivatives, az\dot{o} compound derivatives, perylene derivatives, indigo derivatives, quinacridone derivatives, polycyclic quinone derivatives such as anthraquinones, cyanine derivatives, fullerene derivatives, and derivatives of nitrogen-containing cyclic compounds such as indole, carbazole, oxazole, isoxazole, thiazole, imidazole, pyrazole, oxadiazole, pyrazoline, thiathiazole, and triazole, hydrazine derivatives, triphenylamine derivatives, triphenylmethane derivatives, stilbenes, quinone compound derivatives such as anthraquinone diphenoquinone, and derivatives of polycyclic aromatic compounds such as pentacene, anthracene, pyrene, phenanthrene, and coronene.

Examples in polymer materials are polymers having a structure of any of the above low molecular weight compounds used in a polymer main chain such as a polyethylene chain, a polysiloxane chain, a polyether chain, a polyester chain, a polyamide chain, and a polyimide chain, or polymers having a structure of any of the above low molecular weight compounds bonded as a side chain in a pendant form, or carbon-based conjugated polymers such as aromatic conjugated polymers such as polyparaphenylene, aliphatic conjugated polymers such as polyacetylene, heterocyclic conjugated polymers such as polypyrrole and polythiophene, hetero-atom containing conjugated polymers such as polyanilines and polyphenylene sulfide, and complex conjugated polymers having a structure where alternating conjugated polymer component units are bonded to each other, such as poly (phenylene vinylene) and poly (thienylene vinylene). Further, polysilanes and polymers where an oligosilane structure and a carbon-based conjugated structure are alternately linked to form a chain, such as disilanylene carbon-based conjugated polymer structures such as disilanylenearylene polymers, (disilanylene) ethenylene polymers and (disilanylene) ethynylene polymers may be used. Other materials may be polymer chains including inorganic elements such as phosphorus and nitrogen elements, polymers including a polymer chain with a coordinated aromatic ligand, such as phthalocyanatopoly (siloxane) coordinated, polymers produced by ring condensation of perylenes such as perylenetetracarboxylic acid by heat treatment, ladder polymers produced by heat treatment of cyano group-containing polyethylene derivatives such as polyacrylonitrile, and composite materials including perovskites intercalated with organic compounds.

Any material that has sufficient electrical conductivity may be used as the source and drain electrodes 32 and 33 of the organic thin film transistor without particular limitations. For example, simple metals such as Pt, Au, Cr, W, Ru, Ir, Sc, Ti, V, Mn, Fe, Co, Ni, Zn, Ga, Y, Zr, Nb, Mo, Tc, Rh, Pd, Ag, Cd, Ln, Sn, Ta, Re, Os, Tl, Pb, La, Ce, Pr, Nd, Pm, Sm, Eu, Gd, Tb, Dy, Ho, Er, Tm, Yb, and Lu, or laminates of any of these metals, or compounds of any of these metals may be used. Metal oxides such as ITO (Indium-Tin Oxide) and IZO (Indium-Zinc Oxide) or electrically-conductive organic materials containing conjugated polymer compounds such as polyanilines, polythiophenes and polypyrroles may also be used.

Concerning the gate electrode 30 and the gate insulating film 31 of the organic thin film transistor, an illustrative and non-limiting example is provided where Ta is used for the gate electrode 30, and Ta is anodized to form Ta₂O₅ for the gate insulating film 31. The material for the gate electrode 30 may be any metal as long as it can be anodized, such as a single substance of Al, Mg, Ti, Nb, Zr, or the like, and alloys of any of these metals, and any of these materials may be anodized to form the gate insulating film 31. If the gate insulating film is not formed by anodizing the gate electrode, it is possible to the material the same as that for the source electrode 32 or the drain electrode 33 for the gate electrode 30. In this case, the gate insulating film 31 may be a metal oxide such as LiOₓ, LiN ₓ, NaOₓ, KOₓ, RbOₓ, NaOₓ, CsOₓ, BeOₓ, MgOₓ, MgNₓ, CaOₓ, CaNₓ, SrOₓ, BaOₓ, ScOₓ, YOₓ, YNₓ, LaOₓ, LaNₓ, CeOₓ, PrOₓ, NbOₓ, SmOₓ, EuOₓ, GdOₓ, TbOₓ, DyOₓ, HoOₓ, ErOₓ, TmOₓ, YbOₓ, LuOₓ, TiOₓ, TiNₓ, ZrOₓ, ZrNₓ, HfOₓ, ThOₓ, VOₓ, VNₓ, NbOₓ, TaOₓ, TaNₓ, CrOₓ, MoOₓ, MoNₓ, WOₓ, WNₓ, MnOₓ, ReOₓ, FeOₓ, FeNₓ, RuOₓ, OsOₓ, CoOₓ, RhOₓ, IrOₓ, NiOₓ, PdOₓ, PtOₓ, CuOₓ, CuNₓ, AgOₓ, AuOₓ, ZnOₓ, CdOₓ, HgOₓ, BOₓ, BNₓ, AlOₓ, AlNₓ, GaOₓ, GaNₓ, InOₓ, SiNₓ, GeOₓ, SnOₓ, PbOₓ, POₓ, PNₓ, AsOₓ, SbOₓ, SeOₓ, TeOₓ, a complex metal oxide such as LiAlO₂, Li₂SiO₃, Li₂TiO₃, Na₂Al₂₂0₃₄, Na₄FeO₂, NaSiO₄, K₂SiO₃, K₂TiO₃, K₃WO4, Rb₂CrO₄, Cs₂CrO₄, MgAl₂O₄, MgFe₂O₄, MgTiO₃, CaTiO₃, CaWO₄, CaZrO₃, SrFe₁₂O₁₉, SrTiO₃, SrZrO₃, BaAl₂O₄, BaFe₁₂O₁₉, BaTiO₃, YAl₁₅0₁₂, YFe₅O₁₂, LaFeO₃, LaFe₅O₁₂, La₂Ti₂O₇, CeSnO₄, CeTiO₄, Sm₃Fe₅O₁₂, EuFeO₃, Eu₃Fe₅O₁₂, GdFeO₃, Gd₃Fe₅O₁₂, DyFeO₃, Dy₃Fe₅O₁₂, HoFeO₃, Ho₃Fe₅O₁₂, ErFeO₃, Er₃Fe₅O₁₂, Tm₃Fe₆O₁₂, LuFeO₃, Lu₃Fe₅O₁₂, NiTiO₃, Al₂TiO₃, FeTiO₃, BaZrO₃, LiZrO₃, MgZrO₃, HfTiO₄, NH₄VO₃, AgVO₃, LiVO₃, BaNb₂O₆, NaNbO₃, SrNb₂O₆, KTaO₃, NaTaO₃, SrTa₂O₆, CuCr₂O₄, AgCrO₄, BaCrO₄, K₂MoO₄, Na₂MoO₄, NiMoO₄, BaWO₄, Na₂WO₄, SrWO₄, MnCr₂O₄, MnFe₂O₄, MnTiO₃, MnWO₄, CoFe₂O₄, ZnFe₂O₄, Fe₂WO₄, CoMoO₄, CuTiO₃, CuWO₄, Ag₂MoO₄, Ag₂WO₄, ZnAl₂O₄, ZnMoO₄, ZnWO₄, CdSnO₃, CdTiO₃, CdMoO₄, CdWO₄, NaAlO₂, MgAl₂O₄, SrAl₂O₄, Gd₃Ga₅O₁₂, InFeO₃, MgIn₂O₄, Al₂TiO₅, FeTiO₅, MgTiO₃, Na₂SiO₃, CaSiO₃, ZrSiO₄, K₂GeO₃, Li₂GeO₃, Bi₂Sn₃O₉, MgSnO₃, Na₂TeO₄, a sulfide such as FeS, Al₂S₃, MgS, and ZnS, a fluoride such as LiF, MgF₂ and SmF₃, a chloride such as HgCl, FeCl₂ and CrCl₃, a bromide such as AgBr, CuBr and MnBr₂, an iodide such as PbI₂, CuI and FeI₂, or a metal nitride oxide such as SiAlON. A polymer material such as polyimide, polyamide, polyester, polyacrylate, an epoxy resin, a phenol resin, and polyvinyl alcohol is also effectively used to form the gate insulating film.

The method for producing the organic thin film transistor in use of such the materials is not specifically limited in the present invention, and any known conventional method may be used for that. For example, a Ta film for the gate electrode 30 and the storage capacitance 14 is formed on the glass substrate 15 which has been cleaned, and the Ta film is subjected to dry etching in an RIE system to form a desired wiring pattern. In this process, the wiring pattern is designed so that the directions of the gate electrodes 30 of the two organic thin film transistors, namely the switching and driving organic thin film transistors 12 and 13 are respectively in parallel each other and that the directions of the channels of the transistors are respectively in parallel each other. Thereafter, the Ta wiring film is anodized to thereby coat the surface of the Ta with a Ta₂O₅ film, whereby the gate insulating film 31 is formed. Thereafter, a Cr film or an Au film for the source and drain electrodes 32 and 33 is patterned, and a hexamethyldisilazane film 34 is formed on the gate insulating film 31 by a dip coating method. Thus the organic thin film transistor shown in FIG. 2 is formed.

In the organic thin film transistor formed by the materials as described above, a rubbing process is preferably performed with respect to the channel portion, namely on the hexamethyldisilazane film 34 of the organic thin film transistor shown in FIG. 3.

The rubbing process includes rubbing the surface of the film in an identical direction using a fabric such as a felt, a brush or the like. This rubbing process is also called alignment process. Performing this process can improve alignment in organic semiconductors and increase charge mobility of organic thin film transistors. The rubbing direction may be arbitrarily determined depending on a material of channel portion.

The present invention is not limited to the embodiments described above. The above embodiments are presented for illustrative purpose only. All having substantially the same construction as and demonstrating function and effects similar to those in technical idea, which is recited in the scope of claims, reside in the technical scope of the invention.

For example, while a glass substrate is exemplified as the substrate 15 in the above description, the substrate is not limited thereto, and it may be a plastic substrate such as a polyethersulfone (PES) substrate and a polycarbonate (PC) substrate, a laminated substrate of glass and plastic, or a substrate coated with an alkali barrier film or a gas barrier film on its surface.

Further, when an organic thin film transistor is used for the thin filmtransistor and an organic electroluminescence (EL) display element is used for the display portion, the subpixel is preferably sealed in its entirety (not shown) in order to protect them from water or moisture. This sealing method is not specifically limited in the present invention, and for example, a sealed case may be used, or a resin film of an inorganic or polymer material may be used for the sealing.

### EXAMPLES

### Example 1

An example of the invention, the subpixel shown in FIG. 1 is prepared. Organic thin film transistors are used as two transistors forming the subpixel and arranged such that their channels are in parallel each other as shown in FIG. 1. They are produced by the method described above. The rubbing process described above is performed only once with respect to the channels of the two organic thin film transistors. AS to dimensions of the subpixel thus produced, a length of one side of subpixel 10 is 1 mm, a width of switching organic thin film transistor 12 is 400 μm, a width of driving organic thin film transistor 13 is 700 μm, and a length of channel C (distance between electrodes) is 10 μm.

### Comparative Example 1

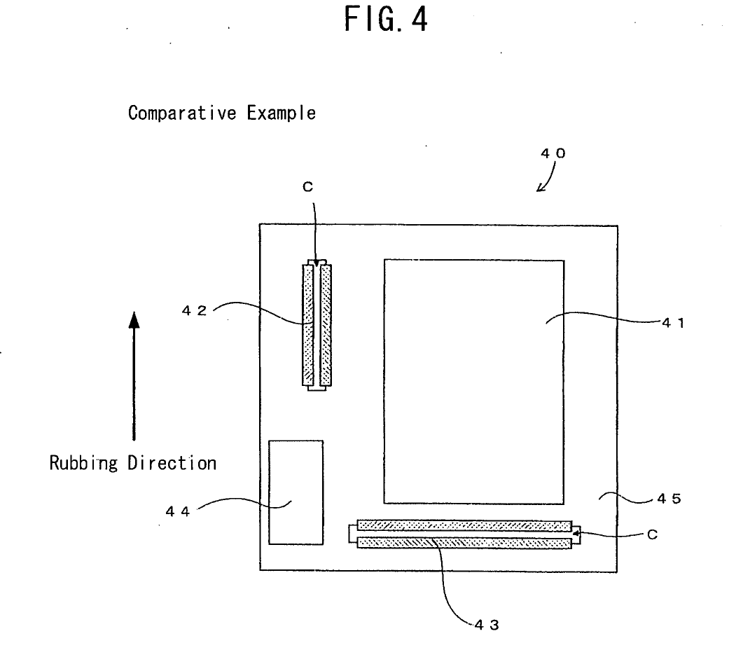

FIG. 4 is a front view of a subpixel according to Comparative Example 1 .

A subpixel shown in FIG. 4 is produced as a comparative example. In this subpixel, two transistors forming a subpixel shown in FIG. 4 are arranged in perpendicular to each other. The two transistors used in this comparative example are produced using the same materials and the same method as in the above Example 1. As to rubbing process, it is carried out once in a direction from bottom up on FIG. 4 (vide the arrow), in other words along the channel of the transistor 42 shown in FIG. 4.

### Results

Charge mobility of the transistors of subpixel in each of Example 1 and Comparative Example 1 is respectively measured. As a result, the transistors of subpixel in Example 1 show a charge mobility value of 0. 23 cm²/Vs and a charge mobility value of 0.21 cm²/Vs, respectively. Meanwhile, in the transistors of subpixel in comparative Example 1, the transistor 42 subjected to rubbing along the channel shows a charge mobility value of 0.21cm²/Vs, while the other transistor 43 shows a charge mobility value of 0.05 cm²/Vs.

Although the subpixels of Example 1 and Comparative Example 1 are the same in their overall size, it is apparent that the display portion 11 of subpixel in Example 1 is larger than the display portion 41.

The results indicate that according to the subpixel of the invention, even when organic or amorphous Si thin film transistors are used, it is possible to ensure a large size of a display portion. Further, according to the subpixel of the invention, since a plurality of thin film transistors are arranged so that their channels are in parallel each other, the plurality of thin film transistors can be rubbed all at once by a single rubbing process, thereby increasing charge mobility in each of the thin film transistors.

On the other hand, as known from Comparative Example 1, if a plurality of thin film transistors are not arranged so that their channels are in parallel each other, the display portion is as much downsized. Further, since a single rubbing process enables treatment with respect to only a channel, formed along the rubbing direction, it is impossible to uniformly rub all of the plurality of thin film transistors, forming the subpixel.

1-5. (canceled)

6. A subpixel forming a pixel of a color display screen, comprising:
one display portion; and
a plurality of thin film transistors for driving the display portion, wherein
the plurality of thin film transistors are arranged such that their channels are in parallel to each another.

7. The subpixel according to claim 6, wherein
provided that a length of one side of the subpixel is 1, a channel width of at least one of the plurality of thin film transistors is 0.4 or more.

8. The subpixel according to claim 6, wherein
the thin film transistors are organic thin film transistors or amorphous Si thin film transistors.

9. The subpixel according to claim 7, wherein
the thin film transistors are organic thin film transistors or amorphous Si thin film transistors.

10. The subpixel according to claim 6, wherein
the display portion is an organic electroluminescence(EL) element.

11. The subpixel according to claim 7, wherein
the display portion is an organic electroluminescence(EL) element.

12. The subpixel according to claim 6, wherein
the channels of the plurality of thin film transistors are subjected to a rubbing process.

13. The subpixel according to claim 7, wherein
the channels of the plurality of thin film transistors are subjected to a rubbing process.
